(19) United States
(12) Patent Application Publication
(10) Pub. No.: US 2026/0130238 A1
(43) Pub. Date: May 7, 2026

(54) SEMICONDUCTOR PACKAGE AND METHOD FOR FABRICATING THE SAME

(71) Applicant: Samsung Electronics Co., Ltd., Suwon-si (KR)

(72) Inventors: Gi Tae PARK, Suwon-si (KR); Jong Bo SHIM, Suwon-si (KR)

(73) Assignee: Samsung Electronics Co., Ltd., Suwon-si (KR)

(21) Appl. No.: 19/251,134

(22) Filed: Jun. 26, 2025

(30) Foreign Application Priority Data
Nov. 7, 2024 (KR) 10-2024-0156894

(51) Int. Cl. H01L 23/538; H01L 23/498; H01L 23/58; H01L 25/04

(52) U.S. Cl. CPC H10W 70/60; H10W 42/00; H10W 70/611; H10W 90/00; H10W 90/701

(57) ABSTRACT

There is provided a semiconductor package having improved reliability. The semiconductor package comprising, a first package including a first package substrate and a first semiconductor chip mounted on the first package substrate, an interposer substrate on the first package, a second package including a second package substrate on the interposer substrate, and the second package substrate including a first surface and a second surface opposite to each other, a plurality of solder balls attached onto the first surface of the second package substrate, and the plurality of solder balls connecting the second package substrate and the interposer substrate, and a second semiconductor chip mounted on the second surface of the second package substrate, and a second capacitor between the interposer substrate and the second package substrate, the second capacitor mounted on the interposer substrate and electrically connected to the second semiconductor chip.

### CROSS-REFERENCE TO RELATED APPLICATION

This application claims priority from Korean Patent Application No. 10-2024-0156894 filed on Nov. 7, 2024 in the Korean Intellectual Property Office, and all the benefits accruing therefrom under 35 U.S.C. 119, the contents of which in its entirety are herein incorporated by reference.

### BACKGROUND

Some example embodiments of inventive concepts relate to a semiconductor package and a method for fabricating the same.

In response to the rapid development of the electronics industry and user's demands, electronic devices are gradually becoming smaller, multifunctional, and larger in capacity, and accordingly, semiconductor packages including a plurality of semiconductor chips may be beneficial.

In order to satisfy some industrial requirements, packaging processes of various methods have been developed. An interposer is an electrical interface that routes connections inside one package and/or between different packages from each other. A purpose of the interposer may be to spread a pitch of the wiring to a wider pitch and/or to reroute the connection to another connection. As a representative technology using such an interposer, there is an IPOP (Interposer Package on Package) which may provide a different semiconductor package on a semiconductor package.

### SUMMARY

Some example embodiments of inventive concepts provide a semiconductor package having improved reliability.

Alternatively or additionally, some example embodiments of inventive concepts provide a method for fabricating a semiconductor package having improved reliability.

However, aspects of the present inventive concepts are not restricted to the example embodiments set forth herein. The above and other aspects of the present inventive concepts will become more apparent to one of ordinary skill in the art to which the example embodiments pertain by referencing the detailed description given below.

Some example embodiments of inventive concepts include a semiconductor package comprising, a first package including a first package substrate and a first semiconductor chip mounted on the first package substrate, an interposer substrate on the first package, a second package including a second package substrate on the interposer substrate, and the second package substrate including a first surface and a second surface opposite to each other, a plurality of solder balls attached onto the first surface of the second package substrate, and the plurality of solder balls connecting the second package substrate and the interposer substrate, and a second semiconductor chip mounted on the second surface of the second package substrate, and a second capacitor between the interposer substrate and the second package substrate, the second capacitor mounted on the interposer substrate, and electrically connected to the second semiconductor chip.

Some example embodiments of inventive concepts include a semiconductor package comprising, a first package including a first package substrate and a first semiconductor chip mounted on the first package substrate, an interposer substrate on the first package, the interposer substrate extending in a first direction and a second direction, and including an internal area and a ball area surrounding the internal area, a second package including a plurality of first solder balls on the ball area, a plurality of second solder balls on the internal area, a second package substrate on the plurality of first solder balls and the plurality of second solder balls, and a second semiconductor chip mounted on the second package substrate, and a second capacitor on the internal area of the interposer substrate, the second capacitor mounted on the interposer substrate, and electrically connected to the second semiconductor chip through the second solder balls.

Some example embodiments of inventive concepts include a method for fabricating a semiconductor package, the method comprising, providing a first package substrate, mounting a first semiconductor chip on the first package substrate, disposing an interposer substrate on the first semiconductor chip, the interposer substrate being electrically connected to the first package substrate, mounting a capacitor on the interposer substrate, and disposing a second package on the capacitor, wherein the second package includes a second package substrate electrically connected to the interposer substrate and a second semiconductor chip mounted on the second package substrate, and the second semiconductor chip being electrically connected to the capacitor.

Some example embodiments of inventive concepts include a semiconductor package comprising a first package including a first package substrate, a first semiconductor ship, and a first capacitor, a second package on the first package, the second package including a second package substrate and a second semiconductor chip, the second package being spaced apart from the first package in a first direction, a second capacitor between the first package substrate and the second package substrate, and a plurality of solder balls between the first package substrate and the second package substrate.

In some example embodiments, the plurality of solder balls include a first plurality of solder balls and a second plurality of solder balls, adjacent first solder balls of the first plurality of solder balls are spaced apart from each other in a second direction by a first distance, adjacent second solder balls of the second plurality of solder balls are spaced apart from each other in the second direction by a second distance, and the first distance is smaller than the second distance.

In some example embodiments, a first solder ball of the first plurality of solder balls and a second solder ball of the second plurality of solder balls are adjacent to each other and spaced apart from each other in the second direction by a third distance, and the first distance is smaller than the third distance.

It should be noted that effects of the present inventive concepts are not limited to those described above, and other effects of the present inventive concepts will be apparent from the following description.

### BRIEF DESCRIPTION OF THE DRAWINGS

The above and other aspects and features of the present inventive concepts will become more apparent by describing in detail illustrative example embodiments thereof with reference to the attached drawings, in which:

FIG. 1 is a conceptual diagram of a semiconductor package according to some example embodiments.

FIG. 2 is a cross-sectional view of the semiconductor package of FIG. 1.

FIG. 3 is a plan view taken along A-A of FIG. 2.

FIG. 4 is an enlarged view of a region P of FIG. 2.

FIG. 5 is a diagram for explaining a connection relationship between a semiconductor chip and a capacitor of the semiconductor package according to some example embodiments.

FIGS. 6 and 7 are diagrams for explaining a semiconductor package according to some example embodiments.

FIGS. 8 and 9 are diagrams for explaining a semiconductor package according to some example embodiments.

FIGS. 10 and 11 are diagrams for explaining a semiconductor package according to some example embodiments.

FIG. 12 is a flowchart for explaining a method for fabricating a semiconductor package according to some example embodiments.

FIGS. 13 to 19 are intermediate stage diagrams for explaining the method for fabricating the semiconductor package according to some example embodiments.

### DETAILED DESCRIPTION

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to the other elements and/or properties thereof. Elements and/or properties thereof that are “the same” or “equal” to other elements and/or properties thereof will be understood to include elements and/or properties thereof that are identical to, the same as, or equal to the other elements and/or properties thereof within manufacturing tolerances and/or material tolerances (e.g., +10%). Elements and/or properties thereof that are identical, the same, and/or equal as other elements and/or properties thereof may be structurally the same or substantially the same, functionally the same or substantially the same, and/or compositionally the same or substantially the same thereof.

As described herein, an element that is “on” another element may be above or beneath or adjacent (e.g., horizontally adjacent) to the other element. An element that is on another element may be directly on the other element, such that the element is in direct contact with the other element. An element that is on another element may be indirectly on the other element, such that the element is isolated from direct contact with the other element by one or more interposing spaces and/or structures.

As will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%).

Hereinafter, some example embodiments according to the present inventive concepts will be described with reference to the accompanying drawings.

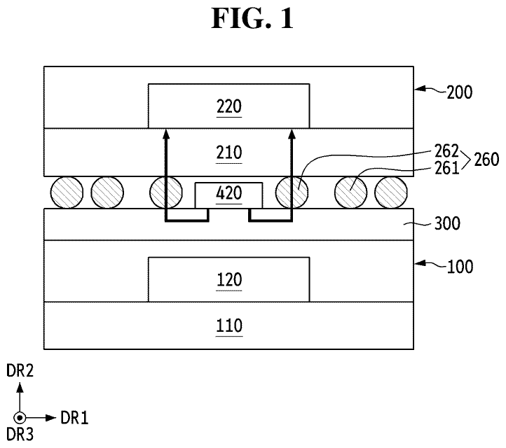

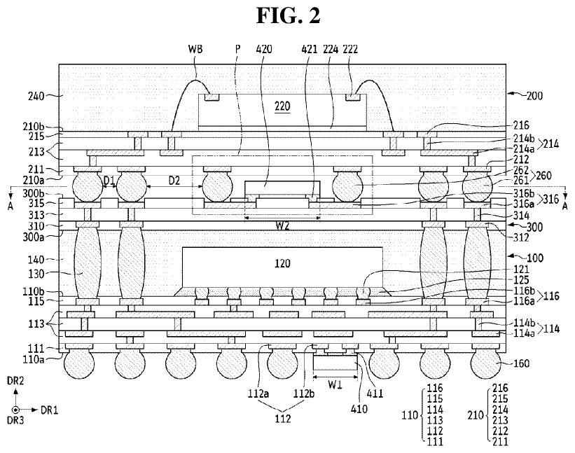

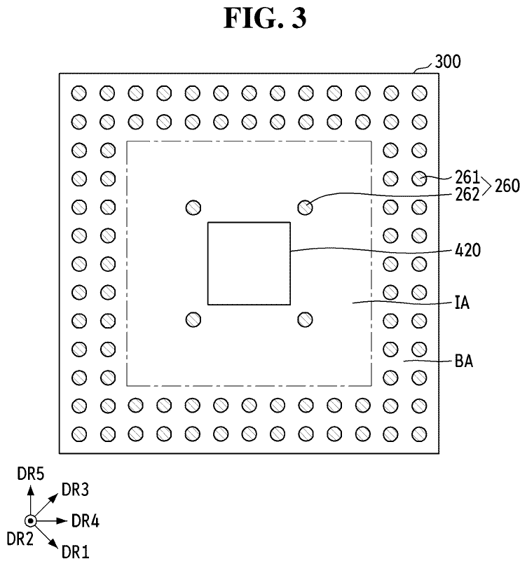

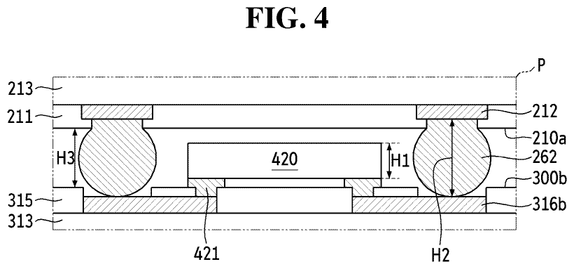

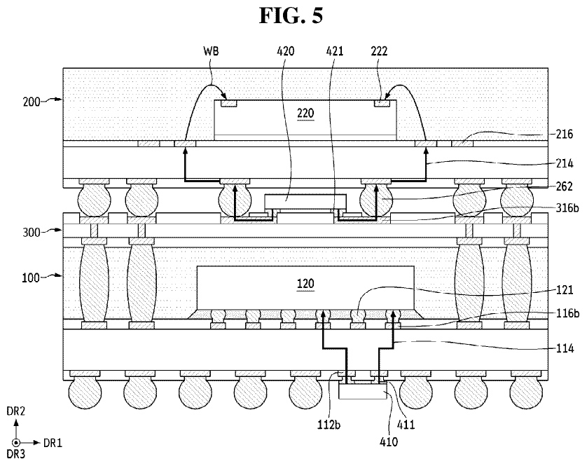

FIG. 1 is a conceptual diagram of a semiconductor package according to some example embodiments. FIG. 2 is a cross-sectional view of the semiconductor package of FIG. 1. FIG. 3 is a plan view taken along A-A of FIG. 2. FIG. 4 is an enlarged view of a region P of FIG. 2. FIG. 5 is a diagram for explaining a connection relationship between a semiconductor chip and a capacitor of the semiconductor package according to some example embodiments.

Referring to FIGS. 1 to 5, a semiconductor package according to some example embodiments may include a first package 100, an interposer substrate 300, a second package 200, a first capacitor 410, and a second capacitor 420.

The first package 100 may include a first package substrate 110, a plurality of first solder balls 160, a first semiconductor chip 120, a plurality of connecting structures 130, and a first mold layer 140.

The first package substrate 110 may include a first surface 110a and a second surface 110b that are opposite to each other in a second direction DR2. The second direction DR2 may be a thickness direction of the first package substrate 110.

The first package substrate 110 may be, for example, a printed circuit board (PCB). The first package substrate 110 may include a first lower protective layer 111, a plurality of first insulating layers 113, a first upper protective layer 115, a first lower wiring 112, a first redistribution structure 114 and a first upper wiring 116.

The first lower protective layer 111, the plurality of first insulating layers 113 and the first upper protective layer 115 may be sequentially stacked in the second direction DR2. Each of the first lower protective layer 111, the plurality of first insulating layers 113 and the first upper protective layer 115 may include an insulating material.

The first lower protective layer 111 and the first upper protective layer 115 may be a solder resist layer. Each of the first lower protective layer 111 and the first upper protective layer 115 may include an insulating resin. For example, each of the first lower protective layer 111 and the first upper protective layer 115 may include at least one of a thermosetting resin such as resin, and a thermoplastic resin such as polyimide, but example embodiments are not limited thereto.

The plurality of first insulating layers 113 may be disposed on the first lower protective layer 111. The plurality of first insulating layers 113 may be disposed between the first lower protective layer 111 and the first upper protective layer 115.

The plurality of first insulating layers 113 are shown as having three layers, but example embodiments are not limited thereto. For example, the plurality of first insulating layers 113 may have two layers. As yet another example, the plurality of first insulating layers 113 may have four layers.

Although the boundaries between the plurality of first insulating layers 113 are shown as being divided, example embodiment are not limited thereto. In some example embodiments, the boundaries between the respective layers of the plurality of first insulating layers 113 may not be divided.

The first insulating layer 113 may include an insulating resin. The first insulating layer 113 may include a thermosetting resin such as an epoxy resin, a thermoplastic resin such as a polyimide, or a resin obtained by impregnating these resins with an inorganic filler and/or a glass fiber (glass fiber, glass cloth, and glass fabric), for example, a photosensitive resin such as prepreg, ABF (Ajinomoto Build up Film), FR-4 (Flame Retardant), BT (Bismaleimide Triazine) or PID (Photo-Imageable Dielectric), but example embodiments are not limited thereto.

The first lower wiring 112 may be disposed in the first lower protective layer 111. The first lower protective layer 111 may include an opening that exposes at least a part of the first lower wiring 112. At least a part of a bottom surface of the first lower wiring 112 may be exposed by the opening of the first lower protective layer 111. The first surface 110a of the first package substrate 110 may be defined by the bottom surface of the first lower protective layer 111 and the exposed bottom surface of the first lower wiring 112.

The first upper wiring 116 may be disposed in the first upper protective layer 115. The first upper protective layer 115 may include an opening that exposes at least a part of the first upper wiring 116. At least a part of the upper surface of the first upper wiring 116 may be exposed by the opening of the first upper protective layer 115. The second surface 110b of the first package substrate 110 may be defined by the upper surface of the first upper protective layer 115 and the exposed upper surface of the first upper wiring 116.

The first redistribution structure 114 may be disposed in the first insulating layer 113. The first redistribution structure 114 may connect the first lower wiring 112 and the first upper wiring 116. Each of the first lower wiring 112 and the first upper wiring 116 may come into contact with the first redistribution structure 114. The first lower wiring 112 and the first upper wiring 116 may be electrically connected through the first redistribution structure 114.

The first redistribution structure 114 may include a plurality of first vertical wirings 114b and a plurality of first horizontal wirings 114a. The first vertical wirings 114b and the first horizontal wirings 114a may be alternately stacked.

The first vertical wirings 114b may extend in the second direction DR2. The first vertical wirings 114b may connect the first lower wiring 112 and the first horizontal wirings 114a. The first vertical wirings 114b may connect the adjacent first horizontal wirings 114a to each other. The first vertical wirings 114b may connect the first upper wiring 116 and the first horizontal wirings 114a.

Each of the first lower wiring 112, the first upper wiring 116, the first vertical wiring 114b, and the first horizontal wiring 114a may include a conductive material. For example, each of the first lower wiring 112, the first upper wiring 116, the first vertical wiring 114b, and the first horizontal wiring 114a may include copper (Cu), but example embodiments are not limited thereto.

The plurality of first solder balls 160 may be disposed on the first surface 110a of the first package substrate 110. The plurality of first solder balls 160 may be disposed on the first lower wiring 112. The plurality of first solder balls 160 may be spaced apart from each other in the first direction DR1. The first solder balls 160 may be attached onto the first surface 110a of the first package substrate 110. The first solder balls 160 may be electrically connected to the first lower wiring 112. The first solder balls 160 may come into contact with the bottom surface of the first lower wiring 112.

The first solder balls 160 may have the form of a ball, a pin or a lead. The first solder ball 160 may include a conductive material. For example, the first solder ball 160 may include tin (Sn), indium (In), bismuth (Bi), antimony (Sb), copper (Cu), silver (Ag), zinc (Zn), lead (Pb), and combinations thereof, but example embodiments are not limited thereto.

The first semiconductor chip 120 may be disposed on the second surface 110b of the first package substrate 110. The first semiconductor chip 120 may be mounted on the second surface 110b of the first package substrate 110. The first semiconductor chip 120 may be connected to the first upper wiring 116.

For example, the first semiconductor chip 120 may be connected to the first upper wiring 116 through a plurality of first bumps 121. The plurality of first bumps 121 may be disposed between the first semiconductor chip 120 and the first package substrate 110. The plurality of first bumps 121 may be spaced apart from each other in the first direction DR1. The first bumps 121 may include a conductive material. A first underfill 125 may fill a space between the first semiconductor chip 120 and the first package substrate 110. The first underfill 125 may surround the first bumps 121. The first underfill 125 may be formed in a capillary underfill manner. The first underfill 125 may include an epoxy resin.

As yet another example, the first semiconductor chip 120 may be connected to the first upper wiring 116 through wire bonding. The first semiconductor chip 120 may be attached onto the first package substrate 110 by an adhesive layer such as a Die Attach Film (DIF) or a Non Conductive Film (NCF). Pads (not shown in FIGS. 1-5) may be disposed on an upper surface of the first semiconductor chip 120, the upper surface being opposite to a bottom surface of the first semiconductor chip 120 to which the adhesive layer is attached. The wires may connect the first upper wiring 116 and the pads.

The first semiconductor chip 120 may be electrically connected to the outside. For example, the first semiconductor chip 120 may be electrically connected to the outside through the first package substrate 110 and the first solder balls 160. The first semiconductor chip 120 may transmit and receive signals to and from the outside. The first semiconductor chip 120 may be supplied with power from the outside.

The first semiconductor chip 120 may be an integrated circuit (IC) in which several semiconductor elements (e.g., hundreds to millions of semiconductor elements) are integrated into one chip. For example, the first semiconductor chip 120 may be a memory semiconductor chip such as a volatile memory (e.g., a DRAM) or a non-volatile memory (e.g., a ROM or a flash memory). As yet another example, the first semiconductor chip 120 may be an application processor (AP) chip such as a central processing unit (CPU), a graphic processing unit (GPU), a field-programmable gate array (FPGA), a digital signal processor, an encryption processor, a microprocessor or a microcontroller; and a logic semiconductor chip such as an analog-digital converter (ADC) or an application-specific IC (ASIC), but example embodiments are not limited thereto.

The plurality of connecting structures 130 may be disposed on the second surface of the first package substrate 110b. The plurality of connecting structures 130 may be spaced apart from each other in the first direction DR1.

The plurality of connecting structures 130 may be disposed on the first upper wiring 116. The first upper wiring 116 may include a first portion 116a and a second portion 116b. The connecting structure 130 may be connected to the first portion 116a of the first upper wiring 116. The connecting structure 130 may come into contact with the first portion 116a of the first upper wiring 116. The first bump 121 may be connected to the second portion 116b of the first upper wiring 116. The first bump 121 may come into contact with the second portion 116b of the first upper wiring 116.

The plurality of connecting structures 130 may be disposed on a side wall of the first semiconductor chip 120. From a planar view point, the plurality of connecting structures 130 may surround the first semiconductor chip 120. The connecting structure 130 may be spaced apart from the first semiconductor chip 120 in the first direction DR1. A height of the connecting structure 130 in the second direction DR2 may be greater than a height of the first semiconductor chip 120 in the second direction DR2.

The connecting structure 130 may have a pillar shape. The connecting structure 130 may include a conductive material. The connecting structure 130 may include, for example, tin (Sn), indium (In), bismuth (Bi), antimony (Sb), copper (Cu), silver (Ag), zinc (Zn), lead (Pb), and combinations thereof, but example embodiments are not limited thereto.

The first mold layer 140 may be disposed on the second surface 110b of the first package substrate 110. The first mold layer 140 may be disposed between the plurality of first connecting structures 130. The first mold layer 140 may be disposed between the first connecting structure 130 and the first semiconductor chip 120. The first mold layer 140 may surround a side wall of the first connecting structure 130.

The first mold layer 140 may surround the first semiconductor chip 120. For example, the first mold layer 140 may cover the upper surface of the first semiconductor chip 120, the side wall of the first semiconductor chip 120, and the side wall of the first underfill 125.

The boundary between the first mold layer 140 and the first underfill 125 is shown as being divided, but example embodiments are not limited thereto. In some example embodiments, the first mold layer 140 and the first underfill 125 may be formed simultaneously in a molded unfill (MUF) manner. In some example embodiments, the boundary between the first mold layer 140 and the first underfill 125 may not be divided (e.g., the first mold layer 140 and the first underfill 125 may be a single continuous structure).

The first mold layer 140 may include an insulating material. The first mold layer 140 may include, for example, an epoxy molding compound (EMC), but example embodiments are not limited thereto.

An interposer substrate 300 may be disposed on the first package 100. The interposer substrate 300 may be disposed on the second surface 110b of the first package substrate 110.

The first semiconductor chip 120 and the first connecting structure 130 may be disposed between the first package substrate 110 and the interposer substrate 300. The first semiconductor chip 120 may be spaced apart from the interposer substrate 300 in the second direction DR2. The first connecting structure 130 may connect the first package substrate 110 and the interposer substrate 300. The first mold layer 140 may fill the space between the first package substrate 110 and the interposer substrate 300.

The interposer substrate 300 may be a redistribution substrate including an insulating layer and a redistribution layer. The interposer substrate 300 may electrically connect the first package 100 and a second package 200 to be described below.

The interposer substrate 300 may include a first surface 300a and a second surface 300b that are opposite to each other in the second direction DR2. The first surface 300a of the interposer substrate 300 may be a surface that is closer to the first package 100 than the second surface 300b of the interposer substrate 300.

Referring to FIG. 3, from a planar view point, the interposer substrate 300 may extend in a fourth direction DR4 and a fifth direction DR5 different from the fourth direction DR4. The fourth direction DR4 may intersect the fifth direction DR5. A plane formed by the fourth direction DR4 and the fifth direction DR5 may correspond to the second surface 300b of the interposer substrate 300. The first direction DR1 may be a direction parallel to the second surface 300b of the interposer substrate 300. The third direction DR3 may be a direction which is parallel to the second surface 300b of the interposer substrate 300 and intersects the first direction DR1.

The interposer substrate 300 may include an internal area IA and a ball area BA. The internal area IA may extend in the fourth direction DR4 and the fifth direction DR5. The ball area BA may surround the internal area IA.

The interposer substrate 300 may include a third lower protective layer 310, a third insulating layer 313, a third upper protective layer 315, a third lower wiring 312, a third redistribution structure 314, and a third upper wiring 316.

The third lower protective layer 310, the third insulating layer 313, and the third upper protective layer 315 may be sequentially stacked on the first package 100 in the second direction DR2. The third lower protective layer 310 may come into contact with the first mold layer 140. Each of the third lower protective layer 310, the third insulating layer 313, and the third upper protective layer 315 may include an insulating material.

The third lower protective layer 310 and the third upper protective layer 315 may be solder resist layers. Each of the third lower protective layer 310 and the third upper protective layer 315 may include an insulating resin. For example, each of the third lower protective layer 310 and the third upper protective layer 315 may include at least one of a thermosetting resin such as resin, and a thermoplastic resin such as polyimide, but example embodiments are not limited thereto.

The third insulating layer 313 may be disposed between the third lower protective layer 310 and the third upper protective layer 315. Although the third insulating layer 313 is shown to have a single layer, example embodiments are not limited thereto. For example, the third insulating layer 313 may have a structure in which a plurality of layers are stacked.

The third insulating layer 313 may include an insulating resin. The third insulating layer 313 may include a thermosetting resin such as an epoxy resin, a thermoplastic resin such as a polyimide, or a resin obtained by impregnating these resins with an inorganic filler and/or a glass fiber (glass fiber, glass cloth, and glass fabric), for example, a photosensitive resin such as prepreg, ABF (Ajinomoto Build-up Film), FR-4 (Flame Retardant), BT (Bismaleimide Triazine) or PID (Photo-Imageable Dielectric), but example embodiments are not limited thereto.

The third lower wiring 312 may be disposed in the third lower protective layer 310. The third lower protective layer 310 may include an opening that exposes at least a part of the third lower wiring 312. At least a part of the bottom surface of the third lower wiring 312 may be exposed by the opening of the third lower protective layer 310. The first surface 300a of the interposer substrate 300 may be defined by the bottom surface of the third lower protective layer 310 and the exposed bottom surface of the third lower wiring 312.

The third lower wiring 312 may be connected to the connecting structure 130. The bottom surface of the third lower wiring 312 may come into contact with the connecting structure 130. The third lower wiring 312 may be electrically connected to the first upper wiring 116 through the connecting structure 130.

The third upper wiring 316 may be disposed in the third upper protective layer 315. The third upper protective layer 315 may include an opening that exposes at least a part of the third upper wiring 316. At least a part of the upper surface of the third upper wiring 316 may be exposed by the opening of the third upper protective layer 315. The second surface 300b of the interposer substrate 300 may be defined by the upper surface of the third upper protective layer 315 and the exposed upper surface of the third upper wiring 316.

The third redistribution structure 314 may be disposed in the third insulating layer 313. The third redistribution structure 314 may connect the third lower wiring 312 and the third upper wiring 316. Each of the third lower wiring 312 and the third upper wiring 316 may come into contact with the third redistribution structure 314. The third lower wiring 312 and the third upper wiring 316 may be electrically connected to each other through the third redistribution structure 314.

The third redistribution structure 314 is shown to include only a vertical wiring, but example embodiments are not limited thereto. For example, the third redistribution structure 314 may include a vertical wiring and a horizontal wiring that are alternately stacked. The vertical wiring and the horizontal wiring may be connected to each other.

Each of the third lower wiring 312, the third upper wiring 316, and the third redistribution structure 314 may include a conductive material. For example, each of the third lower wiring 312, the third upper wiring 316, and the third redistribution structure 314 may include copper (Cu), but example embodiments are not limited thereto.

The second package 200 may be disposed on the second surface 300b of the interposer substrate 300. The second package 200 may include a second package substrate 210, a plurality of second solder balls 260, a second semiconductor chip 220, and a second mold layer 240.

The second package substrate 210 may include a first surface 210a and a second surface 210b that are opposite to each other in the second direction DR2. The first surface 210a of the second package substrate 210 may be a face that is closer to the interposer substrate 300 than the second surface 210b of the second package substrate 210.

The second package substrate 210 may be, for example, a printed circuit board (PCB). The second package substrate 210 may include a second lower protective layer 211, a plurality of second insulating layers 213, a second upper protective layer 215, a second lower wiring 212, a second redistribution structure 214, and a second upper wiring 216.

The second lower protective layer 211, the plurality of second insulating layers 213 and the second upper protective layer 215 may be sequentially stacked on the interposer substrate 300 in the second direction DR2. Each of the second lower protective layer 211, the plurality of second insulating layers 213 and the second upper protective layer 215 may include an insulating material.

The second lower protective layer 211 and the second upper protective layer 215 may be solder resist layers. Each of the second lower protective layer 211 and the second upper protective layer 215 may include an insulating resin. For example, the second lower protective layer 211 and the second upper protective layer 215 may each include at least one of a thermosetting resin such as a resin, and a thermoplastic resin such as a polyimide, but example embodiments are not limited thereto.

The plurality of second insulating layers 213 may be disposed on the second lower protective layer 211. The plurality of second insulating layers 213 may be disposed between the second lower protective layer 211 and the first upper protective layer 115.

The plurality of second insulating layers 213 are shown to have two layers, but example embodiments are not limited thereto. For example, the plurality of second insulating layers 213 may have one layer. As yet another example, the plurality of first insulating layers 113 may have three layers.

Although the boundaries between each layer of the plurality of second insulating layers 213 are shown as being divided, example embodiments are not limited thereto. In some example embodiments, the boundaries between the respective layers of the plurality of second insulating layers 213 may not be divided (e.g., the respective layers of the plurality of second insulating layers 213 may be a single continuous layer).

The second insulating layer 213 may include an insulating resin. The second insulating layer 213 may include a thermosetting resin such as an epoxy resin, a thermoplastic resin such as a polyimide, or a resin obtained by impregnating these resins with an inorganic filler and/or a glass fiber (glass fiber, glass cloth, and glass fabric), for example, a photosensitive resin such as prepreg, ABF (Ajinomoto Build up Film), FR-4 (Flame Retardant), BT (Bismalcimide Triazine) or PID (Photo-Imageable Dielectric), but example embodiments are not limited thereto.

The second lower wiring 212 may be disposed in the second lower protective layer 211. The second lower protective layer 211 may include an opening that exposes at least a part of the second lower wiring 212. At least a part of the bottom surface of the second lower wiring 212 may be exposed by the opening of the second lower protective layer 211. The first surface 210a of the second package substrate 210 may be defined by the bottom surface of the second lower protective layer 211 and the exposed bottom surface of the second lower wiring 212.

The second upper wiring 216 may be disposed in the second upper protective layer 215. The second upper protective layer 215 may include an opening that exposes at least a part of the second upper wiring 216. At least a part of the upper surface of the second upper wiring 216 may be exposed by the opening of the second upper protective layer 215. The second surface 210b of the second package substrate 210 may be defined by the upper surface of the second upper protective layer 215 and the exposed upper surface of the second upper wiring 216.

The second redistribution structure 214 may be disposed in the second insulating layer 213. The second redistribution structure 214 may connect the second lower wiring 212 and the second upper wiring 216. Each of the second lower wiring 212 and the second upper wiring 216 may come into contact with the second redistribution structure 214. The second lower wiring 212 and the second upper wiring 216 may be electrically connected to each other through the second redistribution structure 214.

The second redistribution structure 214 may include a plurality of second vertical wirings 214b and a plurality of second horizontal wirings 214a. The plurality of second vertical wirings 214b and the plurality of second horizontal wirings 214a may be alternately stacked.

The plurality of second vertical wirings 214b may extend in the second direction DR2. The plurality of second vertical wirings 214b may connect the second lower wiring 212 and the plurality of second horizontal wirings 214a. The plurality of second vertical wirings 214b may connect adjacent second horizontal wirings of the plurality of second horizontal wirings 214a to each other. The plurality of second vertical wirings 214b may connect the second upper wiring 216 and the plurality of second horizontal wirings 214a.

Each of the second lower wiring 212, the second upper wiring 216, the plurality of second vertical wirings 214b, and the plurality of second horizontal wirings 214a may include a conductive material. For example, each of the second lower wiring 212, the second upper wiring 216, the plurality of second vertical wirings 214b, and the plurality of second horizontal wirings 214a may include copper (Cu), but example embodiments are not limited thereto.

A plurality of second solder balls 260 may be disposed on the interposer substrate 300. The plurality of second solder balls 260 may be disposed between the interposer substrate 300 and the second package substrate 210. The plurality of second solder balls 260 may be attached onto the first surface 210a of the second package substrate 210. The plurality of second solder balls 260 may be spaced apart from each other in the first direction DR1.

Each second solder ball 260 may connect the interposer substrate 300 and the second package substrate 210. Each second solder ball 260 may come into contact with the upper surface of the third upper wiring 316 and the bottom surface of the second lower wiring 212. The interposer substrate 300 and the second package substrate 210 may be electrically connected through the second solder ball 260.

The second solder ball 260 may have the form of a ball, a pin or a lead. The second solder ball 260 may include a conductive material. For example, the second solder ball 260 may include tin (Sn), indium (In), bismuth (Bi), antimony (Sb), copper (Cu), silver (Ag), zinc (Zn), lead (Pb), and combinations thereof, but example embodiments are not limited thereto.

The second solder ball 260 may include a plurality of first sub-solder balls 261 and a plurality of second sub-solder balls 262.

Referring to FIG. 3, the plurality of first sub-solder balls 261 may be disposed on the ball area BA of the interposer substrate 300. The plurality of first sub-solder balls 261 may be arranged along a fourth direction DR4 and a fifth direction DR5. The plurality of first sub-solder balls 261 may be electrically connected to the connecting structure 130 of the first package 100. The plurality of first sub-solder balls 261 may overlap the connecting structure 130 in the second direction DR2. The plurality of first sub-solder balls 261 may not overlap the first semiconductor chip 120 in the second direction DR2.

The plurality of second sub-solder balls 262 may be disposed on the internal area IA of the interposer substrate 300. The plurality of second sub-solder balls 262 may be electrically connected to a second capacitor 420 to be described below. The plurality of second sub-solder balls 262 may overlap the first semiconductor chip 120 in the second direction DR2.

The second semiconductor chip 220 may be disposed on the second surface 210b of the second package substrate 210. The second semiconductor chip 220 may be mounted on the second surface 210b of the second package substrate 210. The second semiconductor chip 220 may be connected to the second upper wiring 216.

In some example embodiments, the second semiconductor chip 220 may be connected to the second upper wiring 216 through the wire bonding. The second semiconductor chip 220 may be attached onto the second package substrate 210 by an adhesive layer 224, such as a Die Attach Film (DAF) or a Non Conductive Film (NCF). The pads 222 may be disposed on the upper surface of the second semiconductor chip 220 opposite to the bottom surface of the second semiconductor chip 220 to which the adhesive layer is attached. The wires WB may connect the second upper wiring 216 and the pads 222.

The second semiconductor chip 220 may be electrically connected to the first semiconductor chip 120. For example, the second semiconductor chip 220 may be electrically connected to the first semiconductor chip 120 through the first package substrate 110, the connecting structure 130, the interposer substrate 300, the plurality of first sub-solder balls 261, and the second package substrate 210. The second semiconductor chip 220 may transmit and receive signals to and from the first semiconductor chip 120.

The second semiconductor chip 220 may be electrically connected to the outside. For example, the second semiconductor chip 220 may be electrically connected to the outside through the first solder balls 160, the first package substrate 110, the connecting structure 130, the interposer substrate 300, the plurality of first sub-solder balls 261, and the second package substrate 210. The second semiconductor chip 220 may transmit and receive signals to and from the outside. The second semiconductor chip 220 may be supplied with power from the outside.

The second semiconductor chip 220 may be an integrated circuit (IC) in which several semiconductor elements (e.g., hundreds to millions of semiconductor elements) are integrated into one chip. For example, the second semiconductor chip 220 may be a memory semiconductor chip, such as a volatile memory (e.g., a DRAM) or a non-volatile memory (e.g., a ROM or a flash memory). As yet another example, the second semiconductor chip 220 may be an application processor (AP) chip, such as a central processing unit (CPU), a graphic processing unit (GPU), a field-programmable gate array (FPGA), a digital signal processor, an encryption processor, a microprocessor, or a microcontroller; and a logic semiconductor chip such as an analog-digital converter (ADC) or an application-specific IC (ASIC), but example embodiments are not limited thereto.

In some example embodiments, the first semiconductor chip 120 and the second semiconductor chip 220 may be different types of semiconductor chips. For example, the first semiconductor chip 120 may be a logic semiconductor chip, and the second semiconductor chip 220 may be a memory semiconductor chip. In some example embodiments, the first semiconductor chip 120 and the second semiconductor chip 220 may be the same type of semiconductor chip. For example, both the first semiconductor chip 120 and the second semiconductor chip 220 may be a memory semiconductor chip.

The second mold layer 240 may be disposed on the second surface 210b of the second package substrate 210. The first mold layer 140 may surround the second semiconductor chip 220. For example, the second mold layer 240 may cover the upper surface of the second semiconductor chip 220, and the side wall of the second semiconductor chip 220.

The second mold layer 240 may include an insulating material. The first mold layer 140 may include, for example, an epoxy molding compound (EMC), but example embodiments are not limited thereto.

The first capacitor 410 may be disposed on the first surface 110a of the first package substrate 110. The first capacitor 410 may be disposed between adjacent first solder balls 160.

The first capacitor 410 may be mounted on the first surface 110a of the first package substrate 110. The first lower wiring 112 may include a first portion 112a connected to the first solder ball 160, and a second portion 112b connected to the first capacitor 410. The first adhesive member 411 may be disposed between the first capacitor 410 and the second portion 112b of the first lower wiring 112. The first adhesive member 411 may come into contact with the first capacitor 410 and the second portion 112b of the first lower wiring 112.

The first capacitor 410 may be electrically connected to the first semiconductor chip 120. For example, the first capacitor 410 may be electrically connected to the second portion 112b of the first lower wiring 112 through the first adhesive member 411. The first capacitor 410 may be electrically connected to the first semiconductor chip 120 through the second portion 112b of the first lower wiring 112, the first redistribution structure 114, and the second portion 116b of the first upper wiring 116. The first capacitor 410 may supply power to the first semiconductor chip 120.

The first adhesive member 411 may be a solder paste. The first adhesive member 411 may include a conductive material. The first adhesive member 411 may include, for example, tin (Sn), indium (In), bismuth (Bi), antimony (Sb), copper (Cu), silver (Ag), zinc (Zn), lead (Pb), and combinations thereof, but example embodiments are not limited thereto.

The first capacitor 410 may be any one of a multi-layer ceramic capacitor (MLCC), a silicon capacitor, and a low inductance ceramic capacitor (LICC), but example embodiments are not limited thereto.

The second capacitor 420 may be disposed on the second surface 300b of the interposer substrate 300. The second capacitor 420 may be disposed on the space between the interposer substrate 300 and the second package substrate 210. The second capacitor 420 may be disposed between the plurality of second sub-solder balls 262. Referring to FIG. 3, the second capacitor 420 may be disposed on the internal area IA of the interposer substrate 300.

Referring to FIG. 4, as the second capacitor 420 is disposed in the space between the interposer substrate 300 and the second package substrate 210, a height H1 of the second capacitor 420 is smaller than a height H2 of the plurality of second sub-solder balls 262. In other words, the height H1 of the second capacitor 420 is smaller than a distance H3 from the second surface 300b of the interposer substrate 300 to the first surface 210a of the second package substrate 210.

The second capacitor 420 may overlap the first semiconductor chip 120 in the second direction DR2. The second capacitor 420 may overlap the second semiconductor chip 220 in the second direction DR2.

The second capacitor 420 may be mounted on the second surface 300b of the interposer substrate 300. In some example embodiments, the second capacitor 420 may be mounted on the second surface 300b of the interposer substrate 300 through a second adhesive member 421. The third upper wiring 316 may include a first portion 316a connected to the plurality of first sub-solder balls 261, and a second portion 316b connected to the plurality of second sub-solder balls 262. The second adhesive member 421 may be disposed between the second capacitor 420 and the second portion 316b of the third upper wiring 316. The second adhesive member 421 may come into contact with the second capacitor 420 and the second portion 316b of the third upper wiring 316.

In some example embodiments, the second capacitor 420 may not be mounted on the second surface 210b of the second package substrate 210.

The second capacitor 420 may be electrically connected to the second semiconductor chip 220. In some example embodiments, the second capacitor 420 may be electrically connected to the second semiconductor chip 220 through the plurality of second sub-solder balls 262. For example, the second capacitor 420 may be electrically connected to the second portion 316b of the third upper wiring 316 through the second adhesive member 421. The second capacitor 420 may be electrically connected to the plurality of second sub-solder balls 262 through the second portion 316b of the third upper wiring 316. The second capacitor 420 may be electrically connected to the second semiconductor chip 220 through the second portion 316b of the third upper wiring 316, the plurality of second sub-solder balls 262, and the second package substrate 210. The second capacitor 420 may supply power to the second semiconductor chip 220.

The second adhesive member 421 may be a solder paste. The second adhesive member 421 may include a conductive material. The second adhesive member 421 may include, for example, tin (Sn), indium (In), bismuth (Bi), antimony (Sb), copper (Cu), silver (Ag), zinc (Zn), lead (Pb), and combinations thereof, but example embodiments are not limited thereto.

The second capacitor 420 may be any one of a multi-layer ceramic capacitor (MLCC), a silicon capacitor, or a low inductance ceramic capacitor (LICC), but example embodiments are not limited thereto.

In some example embodiments, the first capacitor 410 and the second capacitor 420 may be the same type of capacitor. For example, both the first capacitor 410 and the second capacitor 420 may be a multi-layer ceramic capacitor (MLCC). In some example embodiments, the first capacitor 410 and the second capacitor 420 may be different types of capacitors. For example, the first capacitor 410 may be a multi-layer ceramic capacitor (MLCC), and the second capacitor 420 may be a silicon capacitor, but example embodiments are not limited thereto.

In a package-on-package structure in which different packages 100 and 200 are connected through the interposer substrate 300, the second package 200 may be connected to the interposer substrate 300 through the plurality of first sub-solder balls 261 attached onto the first surface 210a of the second package substrate 210. The plurality of first sub-solder balls 261 are attached in the number necessary for the second package 200 to transmit and receive the signals and/or to receive the power. Alternatively or additionally, in order to shorten the connection distance with the connecting structure 130, the plurality of first sub-solder balls 261 are connected to the first portion 316a of the third upper wiring 316 on the ball area BA of the interposer substrate 300. In some example embodiments, there may be an empty space between the interposer substrate 300 and the second package substrate 210 in which the plurality of first sub-solder balls 261 are not disposed.

The semiconductor package according to some example embodiments may include a second capacitor 420 electrically connected to the second semiconductor chip 220. The second capacitor 420 may be disposed in an empty space between the interposer substrate 300 and the second package substrate 210. In some example embodiments, the number of capacitors mounted on the second package substrate 210 decreases, and/or a capacitor may not be mounted on the second package substrate 210. As a result, a space for additionally mounting the second semiconductor chip 220 in the second package 200 may be secured, and a semiconductor package with improved data processing capability may be provided.

Because the second capacitor 420 is disposed in the empty space between the interposer substrate 300 and the second package substrate 210, it may have various sizes as required (or as it may beneficial). For example, referring to FIG. 2, the width W2 of the second capacitor 420 may be larger than the width W1 of the first capacitor 410. As another example, the width W2 of the second capacitor 420 may be equal to the width W1 of the first capacitor 410. As yet another example, the width W2 of the second capacitor 420 may be smaller than the width W1 of the first capacitor 410.

A semiconductor package according to some example embodiments may include a plurality of first sub-solder balls 261 and a plurality of second sub-solder balls 262. The plurality of first sub-solder balls 261 may be disposed between the interposer substrate 300 and the second package substrate 210 to electrically connect the first package 100 and the second package 200. The plurality of second sub-solder balls 262 may be additionally disposed in the empty space between the interposer substrate 300 and the second package substrate 210 in which the plurality of first sub-solder balls 261 may not be disposed, and electrically connects the second capacitor 420 and the second semiconductor chip 220. By further disposing the plurality of second sub-solder balls 262, the bonding force between the interposer substrate 300 and the second package substrate 210 may be strengthened. As a result, a semiconductor package with an improved warpage phenomenon can be provided.

The plurality of second sub-solder balls 262 may be disposed around the second capacitor 420 to electrically connect the second capacitor 420 and the second semiconductor chip 220. The plurality of second sub-solder balls 262 may be disposed at various intervals depending on the mounting position of the second capacitor 420. In some example embodiments, a first separation distance D1 between adjacent first sub-solder balls (of the plurality of first sub-solder balls 261) may be different from a second separation distance D2 between a first sub-solder ball (of the plurality of first sub-solder balls 261) and a second sub-solder ball (of the plurality of second sub-solder balls 262) adjacent to each other. For example, referring to FIG. 2, the first separation distance D1 may be smaller than the second separation distance D2. As yet another example, the first separation distance D1 may be larger than the second separation distance D2. However, since example embodiments are not limited thereto, the first separation distance D1 may be the same as the second separation distance D2.

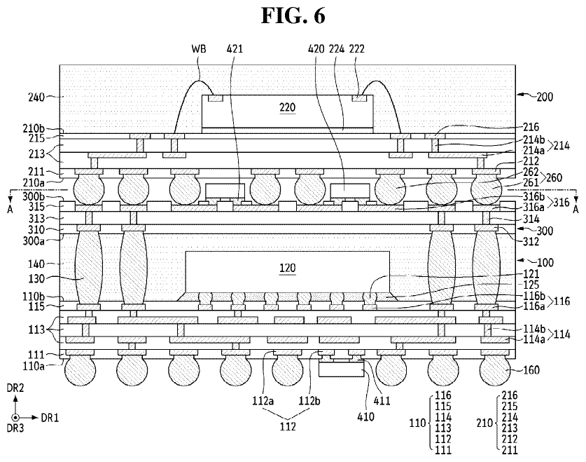

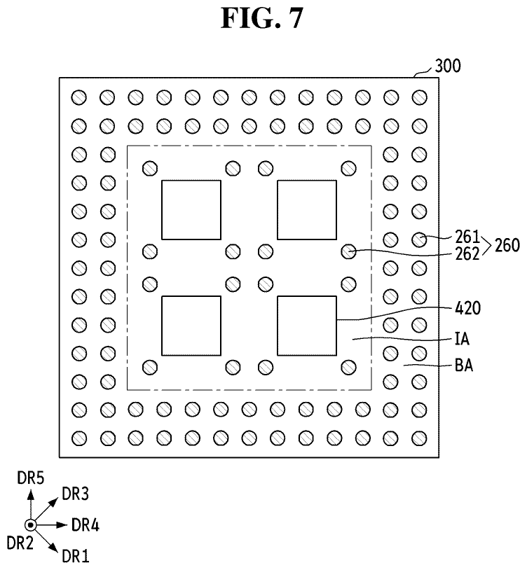

FIGS. 6 and 7 are diagrams for explaining a semiconductor package according to some example embodiments. For reference, FIG. 6 is a cross-sectional view of the semiconductor package according to some example embodiments. FIG. 7 is a plan view taken along A-A of FIG. 6. For convenience of explanation, the following description will focus on differences from the contents described using FIGS. 1 to 5.

Referring to FIGS. 6 and 7, the semiconductor package according to some example embodiments includes a plurality of second capacitors 420.

Each second capacitor of the plurality of second capacitors 420 may be disposed between the plurality of second sub-solder balls 262. The plurality of second capacitors 420 may be spaced apart from one another.

Referring to FIG. 7, although the plurality of second capacitors 420 are shown to be arranged in the form of a matrix and to have the same size, this is only for convenience of explanation, and example embodiments are not limited thereto. The placement of the plurality of second capacitors 420 may be various depending on (or based on) the design, and the sizes of the plurality of second capacitors 420 may be different from one another.

The plurality of second sub-solder balls 262 may be disposed between the plurality of second capacitors 420. One second sub-solder ball (of the plurality of second sub-solder balls 262) may be electrically connected to one second capacitor 420. In some example embodiments, one second sub-solder ball (of the plurality of second sub-solder balls 262) may not be electrically connected to the plurality of second capacitors 420.

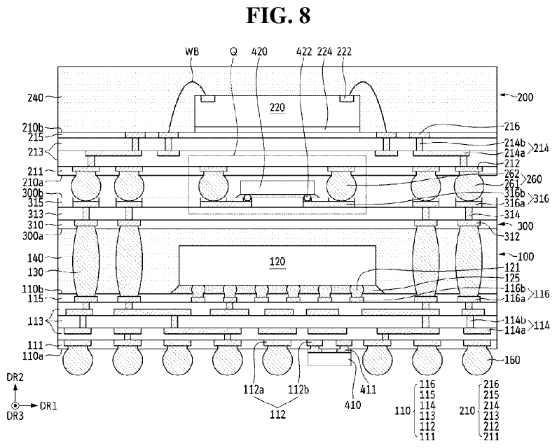

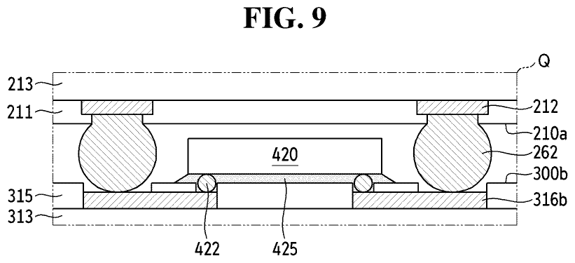

FIGS. 8 and 9 are diagrams for explaining a semiconductor package according to some example embodiments. For reference, FIG. 8 is a cross-sectional view of the semiconductor package according to some example embodiments. FIG. 9 is an enlarged view of a region Q of FIG. 8. For convenience of explanation, differences from the contents explained using FIGS. 1 to 5 will be mainly explained.

Referring to FIGS. 8 and 9, the second capacitor 420 of the semiconductor package according to some example embodiments may be mounted on the second surface 300b of the interposer substrate 300 through a connecting member 422.

The connecting member 422 may be disposed between the second capacitor 420 and the second portion 316b of the third upper wiring 316. The connecting member 422 may come into contact with the second capacitor 420 and the second portion 316b of the third upper wiring 316. The connecting member 422 may connect the second capacitor 420 and the second portion 316b of the third upper wiring 316. The second capacitor 420 may be electrically connected to the plurality of second sub-solder balls 262 through the connecting member 422 and the second portion 316b of the third upper wiring 316.

The connecting member 422 may be a micro bump. The connecting member 422 may include a conductive material. The connecting member 422 may include tin (Sn), indium (In), bismuth (Bi), antimony (Sb), copper (Cu), silver (Ag), gold (Au), zinc (Zn), lead (Pb), and combinations thereof, but example embodiments are not limited thereto.

A third underfill 425 may be disposed between the second capacitor 420 and the second surface 300b of the interposer substrate 300. The third underfill 425 may fill the space between the second capacitor 420 and the second surface 300b of the interposer substrate 300. The third underfill 425 may surround the connecting member 422.

The third underfill 425 may be formed in a capillary underfill manner. The third underfill 425 may include an epoxy resin, but example embodiments are not limited thereto.

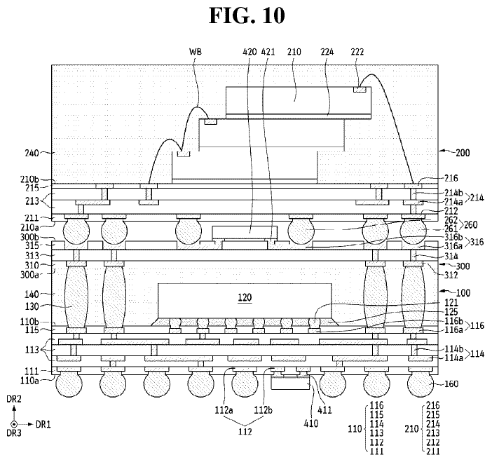

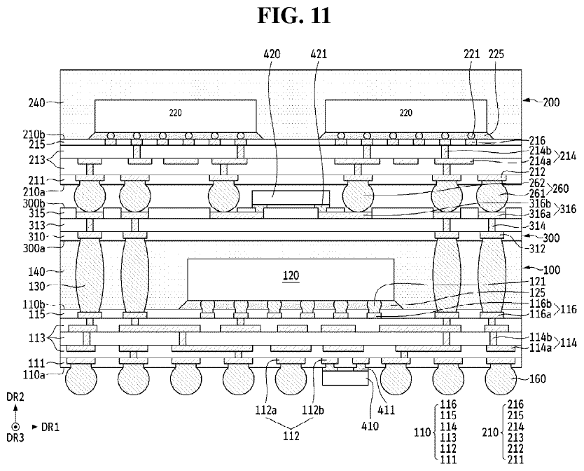

FIGS. 10 and 11 are diagrams for explaining a semiconductor package according to some example embodiments. For convenience of explanation, differences from the contents explained using FIGS. 1 to 5 will be mainly explained.

Referring to FIGS. 10 and 11, the semiconductor package according to some example embodiments may include a plurality of second semiconductor chips 220.

Referring to FIG. 10, a plurality of second semiconductor chips 220 may be stacked in the second direction DR2. An adhesive layer 224 may be disposed between adjacent second semiconductor chips 220. The adhesive layer 224 may come into contact with the adjacent second semiconductor chips 220. The adjacent second semiconductor chips 220 may be bonded to each other through the adhesive layer 224.

The plurality of second semiconductor chips 220 may be connected to each other through wire bonding. The pads 222 may be disposed on the upper surface of each second semiconductor chip 220. The wires WB may connect the pads of each second semiconductor chip 220 to each other.

Each second semiconductor chip 220 may be connected to the second package substrate 210 through the wire bonding. The wires WB may connect the pads of each second semiconductor chip 220 to the second upper wiring 216.

Referring to FIG. 11, the plurality of second semiconductor chips 220 may be mounted on the second surface 210b of the second package substrate 210, respectively. The plurality of second semiconductor chips 220 may be spaced apart from each other in the first direction DR1.

Each second semiconductor chip 220 may be connected to the second upper wiring 216 through the plurality of second bumps 221. The plurality of second bumps 221 may be disposed between the second semiconductor chip 220 and the second package substrate 210. The plurality of second bumps 221 may be spaced apart from each other in the first direction DR1. Each of the second bumps 221 may come into contact with the second upper wiring 216. The second bumps 221 may include a conductive material.

The second underfill 225 may fill a space between the second semiconductor chip 220 and the second package substrate 210. The second underfill 225 may surround the second bumps 221.

The second underfill 225 may be formed in a capillary underfill manner. The second underfill 225 may include an epoxy resin.

The boundary between the second mold layer 240 and the second underfill 225 is shown as being divided, but example embodiments are not limited thereto. In some example embodiments, the second mold layer 240 and the second underfill 225 may be formed simultaneously in a molded unfill (MUF) manner. For example, the boundary between the second mold layer 240 and the second underfill 225 may not be divided.

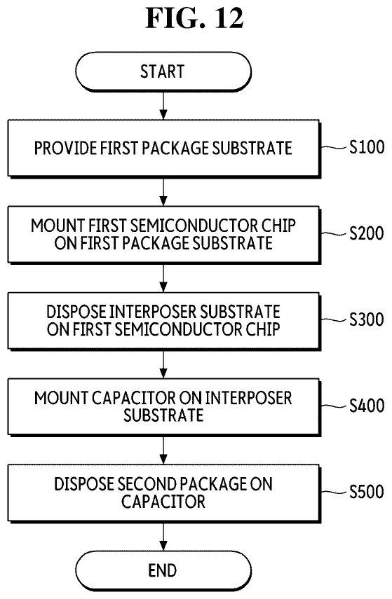

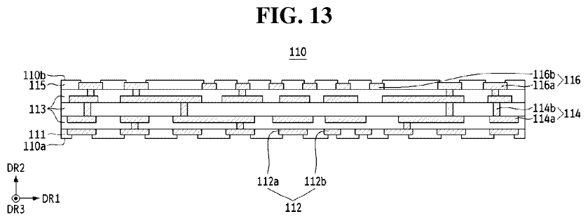

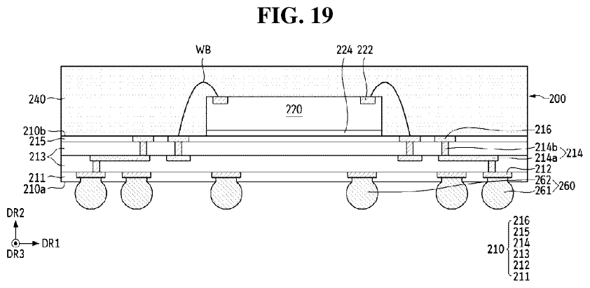

FIG. 12 is a flowchart for explaining a method for fabricating a semiconductor package according to some example embodiments. FIGS. 13 to 19 are intermediate stage diagrams for explaining the method for fabricating the semiconductor package according to some example embodiments. For convenience of explanation, repeated contents as those explained using FIGS. 1 to 5 will be briefly explained or omitted.

Referring to FIGS. 12 and 13, a first package substrate is provided (S100).

The first package substrate 110 may be, for example, a printed circuit board (PCB). The first package substrate 110 may include a first lower protective layer 111, a plurality of first insulating layers 113, a first upper protective layer 115, a first lower wiring 112, a first redistribution structure 114, and a first upper wiring 116.

The first package substrate 110 may include a first surface 110a and a second surface 110b that are opposite to each other in the second direction DR2.

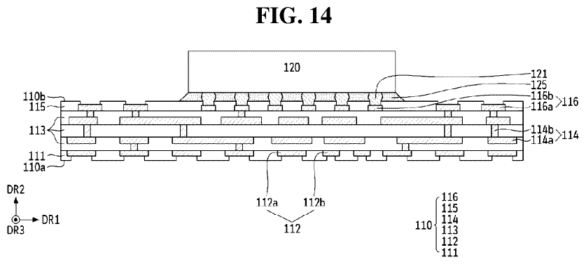

Referring to FIGS. 12 and 14, a first semiconductor chip is mounted on the first package substrate (S200).

The first semiconductor chip 120 is mounted on the second surface 110b of the first package substrate 110. For example, the first semiconductor chip 120 is provided with a plurality of first bumps 121 attached thereto. Each of the first bumps 121 is bonded to the second portion of the first upper wiring 116b.

Next, the first underfill 125 may be formed. The first underfill 125 may be formed in a capillary underfill manner. The first underfill 125 may fill the space between the first semiconductor chip 120 and the first package substrate 110. The first underfill 125 may surround the first bumps 121.

Referring to FIGS. 12, 15, and 16, an interposer substrate is disposed on the first semiconductor chip (S300).

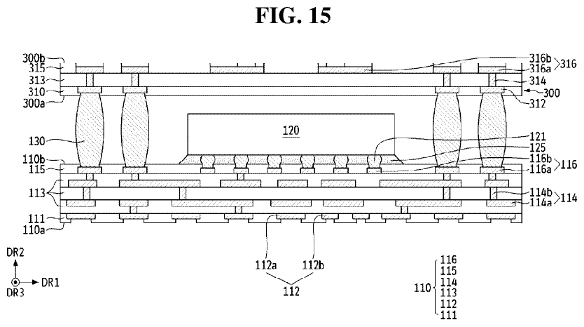

First, referring to FIG. 15, an interposer substrate 300 is provided. The interposer substrate 300 may include a third lower protective layer 310, a third insulating layer 313, a third upper protective layer 315, a third lower wiring 312, a third redistribution structure 314, and a third upper wiring 316. The interposer substrate 300 may include a first surface 300a and a second surface 300b that are opposite to each other in the second direction DR2.

Next, the interposer substrate 300 is disposed on the first semiconductor chip 120.

Next, a connecting structure 130 is formed to bond the first package substrate 110 and the interposer substrate 300. The connecting structure 130 may be formed, for example, by bonding a first sub-connecting structure formed on the first package substrate 110 and a second sub-connecting structure formed on the interposer substrate 300. The interposer substrate 300 may be electrically connected to the first package substrate 110 through the connecting structure 130.

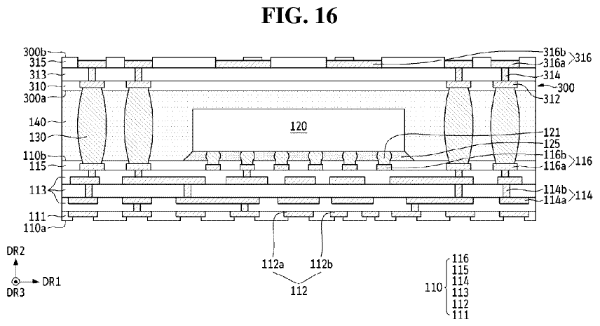

Next, the first mold layer 140 is formed referring to FIG. 16. The first mold layer 140 fills the space between the first package substrate 110 and the interposer substrate 300. The first mold layer 140 covers the first semiconductor chip 120. The first mold layer 140 surrounds the connecting structure 130.

In some example embodiments, the first mold layer 140 may be formed in a molded underfill (MUF) manner. For example, the first mold layer 140 may fill the space between the first package substrate 110 and the first semiconductor chip 120. Therefore, the boundary between the first mold layer 140 and the first underfill 125 may not be divided.

The first mold layer 140 may include an insulating material. The first mold layer 140 may include, for example, an epoxy molding compound (EMC), but example embodiments are not limited thereto.

Referring to FIGS. 12, 17, and 18, a capacitor is mounted on the interposer substrate (S400).

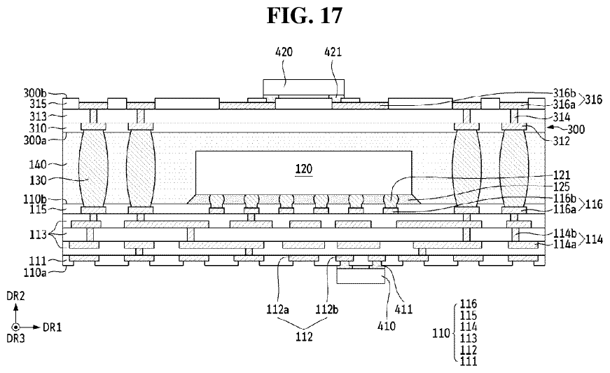

First, referring to FIG. 17, a second capacitor 420 is mounted on the second surface 300b of the interposer substrate 300. For example, a second adhesive member 421 may be formed on the second portion of the third upper wiring 316b. The second adhesive member 421 may be a solder paste. The second capacitor 420 may be bonded to the second adhesive member 421.

As yet another example, the second capacitor 420 may be provided with a connecting member (see 422 of FIG. 9) attached thereto. The connecting member 422 may be a micro bump. The connecting member 422 may be bonded to the second portion of the third upper wiring 316b. Next, a third underfill (425 of FIG. 9) may be formed. The third underfill 425 may fill the space between the interposer substrate 300 and the second capacitor 420. The third underfill 425 may surround the connecting member 422. The third underfill 425 may include an epoxy resin.

Meanwhile, the first capacitor 410 may be mounted on the first surface 110a of the first package substrate 110. A method for mounting the first capacitor 410 may be similar to the method for mounting the second capacitor 420.

The first capacitor 410 may be mounted simultaneously with the second capacitor 420, but example embodiments are not limited thereto.

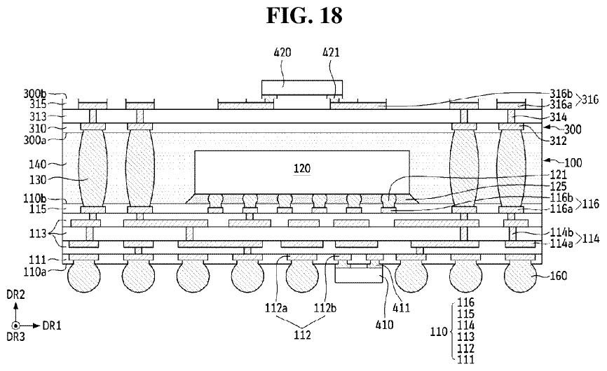

Next, referring to FIG. 18, the first solder ball 160 is attached. The first solder ball 160 is attached onto the first surface 110a of the first package substrate 110. The first solder ball 160 is attached onto the first portion 112a of the first lower wiring 112. The first solder ball 160 may be attached in a reflow manner.

Referring to FIGS. 12, 18 and 2, a second package is disposed on the capacitor (S500).

First, referring to FIG. 18, a second package is provided. The second package 200 may include a second package substrate 210, a plurality of second solder balls 260, a second semiconductor chip 220, and a second mold layer 240.

The second package substrate 210 may include a first surface 210a and a second surface 210b that are opposite to each other in the second direction DR2. The plurality of second solder balls 260 may be provided in the state of being attached onto the first surface 210a of the second package substrate 210. The second semiconductor chip 220 is provided in the state of being mounted onto the second surface 210b of the second package substrate 210.

Next, referring to FIG. 2, the second package 200 is disposed on the second capacitor 420.

Next, the second package 200 is bonded to the interposer substrate 300. In some example embodiments, a plurality of second solder balls 260 are bonded to the interposer substrate 300. For example, each second solder ball 260 is bonded to the third upper wiring 316. The second package substrate 210 is electrically connected to the interposer substrate 300 through the second solder balls 260.

The plurality of second solder balls 260 may include a plurality of first sub-solder balls 261 and a plurality of second sub-solder balls 262. The plurality of first sub-solder balls 261 are bonded to the first portion 316a of the third upper wiring 316. The plurality of second sub-solder balls 262 are bonded to the second portion 316b of the third upper wiring 316. The plurality of first sub-solder balls 261 are electrically connected to the first package substrate 110. The first package substrate 110 is electrically connected to the second package substrate 210 through the connecting structure 130, the interposer substrate 300, and the plurality of first sub-solder balls 261. The plurality of second sub-solder balls 262 are electrically connected to the second capacitor 420. The second capacitor 420 is electrically connected to the second semiconductor chip 220 through the interposer substrate 300, the plurality of second sub-solder balls 262, and the second package substrate 210.

In concluding the detailed description, those skilled in the art will appreciate that many variations and modifications may be made to the example embodiments without substantially departing from the present inventive concepts. Therefore, the example embodiments disclosed herein are used in a generic and descriptive sense only and not for purposes of limiting the present inventive concepts.

What is claimed is:

1. A semiconductor package comprising:
a first package including a first package substrate and a first semiconductor chip mounted on the first package substrate;
an interposer substrate on the first package;
a second package including a second package substrate on the interposer substrate, the second package substrate including,
a first surface and a second surface opposite to each other,
a plurality of solder balls attached onto the first surface of the second package substrate, the plurality of solder balls connecting the second package substrate and the interposer substrate, and
a second semiconductor chip mounted on the second surface of the second package substrate; and
a second capacitor between the interposer substrate and the second package substrate, the second capacitor mounted on the interposer substrate and electrically connected to the second semiconductor chip.

2. The semiconductor package of claim 1, wherein
the first package further includes a plurality of connecting structures connecting the first package substrate and the interposer substrate, and
the plurality of solder balls include a first solder ball electrically connected to the plurality of connecting structures and a second solder ball electrically connected to the second capacitor.

3. The semiconductor package of claim 2,
wherein a separation distance between adjacent first solder balls of the plurality of solder balls is different from a separation distance between the first solder ball and the second solder ball adjacent to each other.

4. The semiconductor package of claim 3,
wherein the separation distance between the adjacent first solder balls of the plurality of solder balls is smaller than the separation distance between the first solder ball and the second solder ball adjacent to each other.

5. The semiconductor package of claim 2,
wherein the interposer substrate includes an upper wiring connecting the second capacitor and the second solder ball.

6. The semiconductor package of claim 1,
wherein the second capacitor is not mounted on the second surface of the second package substrate.

7. The semiconductor package of claim 1,
wherein a height of the second capacitor is smaller than a height of the plurality of solder balls.

8. The semiconductor package of claim 1, further comprising:
a first capacitor on the first package substrate and electrically connected to the first semiconductor chip, wherein
the first package substrate includes a third surface and a fourth surface opposite to each other,
the first capacitor is mounted on the third surface of the first package substrate, and
the first semiconductor chip is mounted on the fourth surface of the first package substrate.

9. The semiconductor package of claim 8,
wherein a width of the second capacitor is greater than a width of the first capacitor.

10. The semiconductor package of claim 1,
wherein the first semiconductor chip is a logic semiconductor chip, and the second semiconductor chip is a memory semiconductor chip.

11. A semiconductor package comprising:
a first package including a first package substrate and a first semiconductor chip mounted on the first package substrate;
an interposer substrate on the first package, the interposer substrate extending in a first direction and a second direction, and including an internal area and a ball area surrounding the internal area;
a second package including,
a plurality of first solder balls on the ball area,
a plurality of second solder balls on the internal area,
a second package substrate on the plurality of first solder balls and the plurality of second solder balls, and
a second semiconductor chip mounted on the second package substrate; and
a second capacitor on the internal area of the interposer substrate, the second capacitor mounted on the interposer substrate, and electrically connected to the second semiconductor chip through the plurality of second solder balls.

12. The semiconductor package of claim 11, wherein
the first package further includes a plurality of connecting structures connecting the first package substrate and the interposer substrate, and
a first solder ball of the plurality of first solder balls is electrically connected to a connecting structure of the plurality of connecting structures.

13. The semiconductor package of claim 11,
wherein a separation distance between adjacent first solder balls of the plurality of first solder balls is different from a separation distance between a first solder ball and a second solder ball adjacent to each other.

14. The semiconductor package of claim 13,
wherein the separation distance between the adjacent first solder balls of the plurality of first solder balls is smaller than the separation distance between the first solder ball and the second solder ball adjacent to each other.

15. The semiconductor package of claim 11,
wherein the second capacitor is not mounted on the second package substrate.

16. The semiconductor package of claim 11, further comprising:
a first capacitor mounted on the first package substrate and electrically connected to the first semiconductor chip.

17. The semiconductor package of claim 11,
wherein the first semiconductor chip is a logic semiconductor chip, and the second semiconductor chip is a memory semiconductor chip.

18. A method for fabricating a semiconductor package, the method comprising:
providing a first package substrate;
mounting a first semiconductor chip on the first package substrate;
disposing an interposer substrate on the first semiconductor chip, the interposer substrate being electrically connected to the first package substrate;
mounting a capacitor on the interposer substrate; and
disposing a second package on the capacitor,
wherein the second package includes a second package substrate electrically connected to the interposer substrate and a second semiconductor chip mounted on the second package substrate, the second semiconductor chip being electrically connected to the capacitor.

19. The method for fabricating a semiconductor package of claim 18,
wherein the disposing of the second package on the capacitor includes bonding a plurality of solder balls to the interposer substrate, the plurality of solder balls being attached onto the second package substrate, and
the plurality of solder balls include first solder balls electrically connected to the first package substrate and second solder balls electrically connected to the capacitor.

20. The method for fabricating a semiconductor package of claim 18,
wherein the disposing of the interposer substrate on the first package substrate includes forming a connecting structure connecting the first package substrate and the interposer substrate.
